(19) United States
(12) Patent Application Publication
(10) Pub. No.: US 2014/0318592 A1
(43) Pub. Date: Oct. 30, 2014

(54) ENHANCEMENT OF THERMOELECTRIC PROPERTIES THROUGH POLARIZATION ENGINEERING

(71) Applicant: The Regents of the University of California, Oakland, CA (US)

(72) Inventors: Alexander Sztein, Goleta, CA (US); John E. Bowers, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 14/367,087

(22) PCT Filed: Dec. 14, 2012
(86) PCT No.: PCT/US12/69684

§ 371 Date: Jun. 19, 2014

Related U.S. Application Data
(60) Provisional application No. 61/578,808, filed on Dec. 21, 2011.

(51) Int. Cl. H01L 35/22; C30B 25/02; H01L 35/34; C30B 23/06

(52) U.S. Cl. CPC H01L 35/22; C30B 23/066; C30B 25/02; H01L 35/34
USPC 136/236.1; 252/62.3 T; 117/105; 117/89

(57) ABSTRACT

A method for enhancement of thermoelectric properties through polarization engineering. Internal electric fields created within a material are used to spatially confine electrons for the purpose of enhancing thermoelectric properties. Electric fields can be induced within a material by the presence of bound charges at interfaces. A combination of spontaneous and piezoelectric polarization can induce this interfacial charge. The fields created by these bound charges have the effect of confining charge carriers near these interfaces. By confining charge carriers to a channel where scattering centers can be deliberately excluded the electron mobility can be enhanced, thus enhancing thermoelectric power factor. Simultaneously, phonons will not be affected by the fields and thus will be subject to the many scattering centers present in the majority of the structure. This allows for simultaneous enhancement of power factor and reduction of thermal conductivity, thus improving the thermoelectric figure of merit, ZT. This approach is also compatible with other strategies for reducing thermal conductivity, for example the inclusion of nanostructures.

### CROSS REFERENCE TO RELATED APPLICATIONS

This application claims the benefit under 35 U.S.C. Section 119(e) of U.S. Provisional Application Ser. No. 61/578,808, filed on Dec. 21, 2011, by Alexander Sztein, John E. Bowers, Steven P. DenBaars, and Shuji Nakamura, and entitled “ENHANCEMENT OF THERMOELECTRIC PROPERTIES THROUGH POLARIZATION ENGINEERING,” attorneys' docket number 30794.443-US-P1 (2012-369-1), which application is hereby incorporated by reference herein.

This application is related to the following co-pending and commonly-assigned application:

U.S. Utility application Number Ser. No. 13/089,138, filed on Apr. 18, 2011, by Hiroaki Ohta, Alexander Sztein, Steven P. DenBaars, and Shuji Nakamura, and entitled “III-V NITRIDE-BASED THERMOELECTRIC DEVICE,” attorney's docket number 30794.304-US-U1 (2009-389-2), which application claims the benefit under 35 U.S.C. Section 119(e) of co-pending and commonly-assigned U.S. Provisional Application Ser. No. 61/325,177, filed on Apr. 16, 2010, by Hiroaki Ohta, Hiroaki Ohta, Alexander Sztein, Steven P. DenBaars, and Shuji Nakamura, entitled “III-V NITRIDE-BASED THERMOELECTRIC DEVICE,” attorney's docket number 30794.304-US-P2 (2009-389-1);
both of which applications are incorporated by reference herein.

### STATEMENT REGARDING FEDERALLY SPONSORED RESEARCH AND DEVELOPMENT

This invention was made with Government support under Grant No. DE-SC0001009 awarded by the Center For Energy Efficient Materials of the U.S. Department of Energy. The Government has certain rights in this invention.

### BACKGROUND OF THE INVENTION

1. Field of the Invention

This invention relates to a method for enhancement of thermoelectric properties through polarization engineering.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Thermoelectric materials are capable of either converting heat into electricity, or using electricity to create a heating or cooling effect. Some of the material parameters that limit the maximum efficiency with which a thermoelectric material can operate are the Seebeck coefficient, electrical conductivity, and thermal conductivity. These parameters can be combined to calculate a general thermoelectric material figure of merit, ZT. Higher ZT values for a material will result in improved efficiencies for devices made using that material.

In typical bulk materials, the Seebeck coefficient typically moves in the opposite direction from electrical conductivity, and electrical conductivity typically moves in the same direction as thermal conductivity when material parameters are changed. This leads to a relatively straightforward optimization using values such as alloy composition and carrier density to maximize ZT. This approach leads to several materials whose ZT nears one; however, further improvement beyond a ZT of 1 is extremely difficult.

Current commercial thermoelectric materials use classical bulk-like properties with spatially uniform charge carriers and typically exhibit ZT near one. The deliberate introduction of interfaces and nanostructures are shown in academic works to reduce thermal conductivity and potentially improve ZT beyond one. In addition, strategies for improving electrical properties have been proposed and focus mainly on the modification of the density of states in a material, or thermionic energy filtering.

The present invention uses a combination of interfacial charges and nanostructured material to break the traditional relationships between Seebeck coefficient and electrical conductivity, and electrical conductivity and thermal conductivity for the purpose of improving ZT. This is accomplished by spatially separating charge carriers into interface charge induced channels, while leaving the spatial phonon distribution largely unchanged. Scattering centers, such as alloy elements or dopant atoms, are then deliberately excluded from the electron rich regions, creating high mobility channels for electrons while maintaining scattering centers for phonons in the remainder of the material. This approach allows the selective scattering of phonons, thus providing a route for improving ZT values beyond traditional thermoelectric materials. In addition, this approach is inherently compatible with simultaneously using deliberately sized nanostructures to further reduce thermal conductivity.

### SUMMARY OF THE INVENTION

To overcome the limitations in the prior art described above, and to overcome other limitations that will become apparent upon reading and understanding the present specification, the present invention discloses a method for enhancement of thermoelectric properties through polarization engineering. Specifically, this invention uses internal electric fields created within a material to spatially confine electrons for the purpose of enhancing thermoelectric properties. Electric fields can be induced within a material by the presence of bound charges at interfaces. In this invention, a combination of spontaneous and piezoelectric polarization induce this interfacial charge. The fields created by these bound charges have the effect of confining charge carriers near these interfaces. By confining charge carriers to a channel where scattering centers can be deliberately excluded, electron mobility can be enhanced, thus enhancing thermoelectric power factor. Simultaneously, phonons will not be affected by the fields and thus will be subject to the many scattering centers present in the majority of the structure. This allows for simultaneous enhancement of power factor and reduction of thermal conductivity, thus improving the thermoelectric figure of merit, ZT. This approach is also compatible with other strategies for reducing thermal conductivity, for example the inclusion of nano structures.

### BRIEF DESCRIPTION OF THE DRAWINGS

Referring now to the drawings in which like reference numbers represent corresponding parts throughout:

FIG. 1(a) is a schematic diagram of Ga-face GaN and FIG. 1(b) is a diagram that shows the orientation of spontaneous polarization charge (not shown is the effect of piezoelectric polarization). This Figure is from D. Brown, PhD Thesis 2010. [8]

FIG. 2(a) is an example structure of a GaN/In_{0.19}Al_{0.81}N superlattice. FIG. 2(b) is a graph of energy (eV) vs. position (Å) that shows the conduction and valence bands for the structure as calculated by BandEng, a 1D self consistent Schrödinger-Poisson solver written by Mike Grundmann. FIG. 2(c) is a graph of carrier density (cm⁻³) vs. position (Å) that shows the electron distribution within the material, wherein the In_{0.19}Al_{0.81}N carrier density is set to 4E19 cm⁻³ and the GaN carrier density is set at 5E18 cm⁻³, and wherein calculations are performed using BandEng.

FIG. 3 illustrates an AlGaN HEMT structure, wherein an AlN spacer is included to keep electrons away from alloy scattering centers in the AlGaN.

FIG. 4 is a Table that shows preliminary results for polarization-based, single layer GaN/AlN/AlGaN thermoelectrics and GaN/AlN/AGaN superlattice thermoelectrics, along with GaN and In_{0.3}Ga_{0.7}N for comparison, wherein data for In_{0.3}Ga_{0.7}N is taken from [7].

FIG. 5 is a flowchart illustrating one method of accomplishing the present invention, where the constituent materials are (Al, Ga, In) N or alloys of these materials.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

The present invention discloses a method of improving ZT beyond bulk values through the use of interfacial properties within a material. By intelligently designing the distribution of charge within a material, the electrical properties can be improved while simultaneously reducing thermal conductivity. This can allow for improved thermoelectric figure of merit, ZT.

In general, the thermal conductivity and electrical conductivity of a material move in the same direction as parameters are changed. This is because many features, such as dopant atoms or grain boundaries, act as both electron and phonon scattering centers, and thus reduce both electrical and thermal conductivity. In order to break this relationship and improve ZT, mechanisms that selectively scatter phonons over electrons must be incorporated into a material. Many have proposed the use of nanostructures for this purpose. In general, the structures that most effectively scatter phonons over electrons have sizes comparable to phonon wavelengths, but significantly larger than electron wavelengths. Nanostructures in the 1-10 nm size range have proven effective for these purposes. [1, 2]

The present invention proposes an alternative method of obtaining selective scattering of phonons over electrons by spatially separating the electrons into channels within a material while the spatial phonon distribution remains unchanged. Scattering centers such as dopant atoms or alloy atoms can then be deliberately excluded from the electron channels while included in most of the material for maximum phonon scattering. The spatial separation of electrons into channels is accomplished by setting up electric fields within a material which will result in sharp potential minima in the conduction band of a material. Such potential minima are known to exist at interfaces in highly polar materials, such as AlGaN/GaN heterostructures. This strategy has been proven effective at increasing electron mobility in high electron mobility transistor (HEMTs) technology, but has never been proposed for use in thermoelectric materials. High electron mobility transistors fabricated from AlGaN/GaN interfaces have achieved electron mobilities as high at 2000 cm²/VS, which is four times higher than typical Gallium Nitride. [3] The thermal conductivity and Seebeck coefficient of such structures has not been investigated prior to this work.

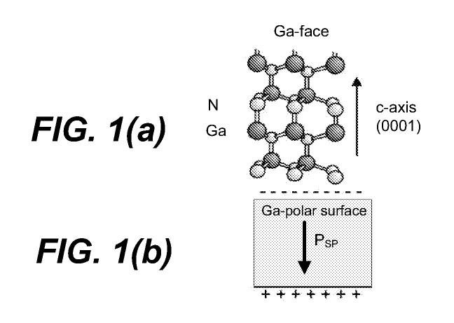

FIG. 1(a) is a schematic diagram of a GaN crystal grown along the c-axis and FIG. 1(b) is a diagram that shows the orientation of spontaneous polarization P_{SP} charge (not shown is the effect of piezoelectric polarization). This orientation has layered gallium and nitrogen atoms. Under typical MOCVD growth conditions for GaN on sapphire, the top surface is Ga terminated, i.e., Ga-face, resulting in a Ga-polar surface. When a different material, for example, AlGaN or InAlN, is grown on top of GaN to form a heterointerface, the electronegativity difference between the atoms on each side of the interface causes the spontaneous polarization P_{SP}.

For c-plane III-Nitride materials, this effect is much larger than is typical for other III-V materials. For example, an AlN/GaN heterointerface has more than 10 times the interface charge in the GaAs/AlGaAs system, which is commonly used for MODFETS. [4]

In addition to spontaneous polarization, piezoelectric polarization can be present at heterointerfaces within a material. This polarization is created when the materials on each side of the interface are piezoelectric materials. Since the materials used on each side of the interface often have different lattice constants, both sides of the interface are strained, and therefore piezoelectric electric fields are created.

Piezoelectric coefficients in III-Nitrides are also typically an order of magnitude larger than most III-V materials. [4] The combination of spontaneous and piezoelectric polarizations at these interfaces can create large polarization charges at interfaces for certain alloy compositions.

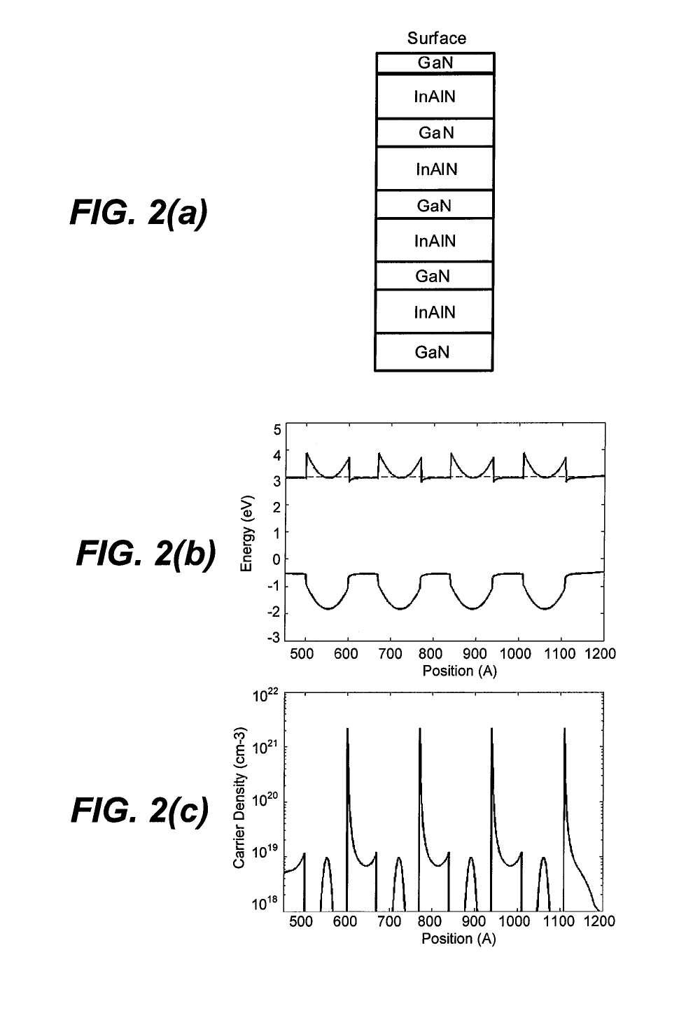

The present invention uses the large polarization charges discussed in the previous section in order to bind charge carriers to interfaces within a material. The structure, band diagram, and carrier distribution for a superlattice of such interfaces are shown in FIGS. 2(a), 2(b) and 2(c). Specifically, FIG. 2(a) is an example structure of a GaN/In_{0.19}A1_{0.81}N superlattice; FIG. 2(b) is a graph of energy (eV) vs. position (Å) that shows the conduction and valence bands for the structure as calculated by the BandEng simulation software, which is a 1D self consistent Schrödinger-Poisson solver; and FIG. 2(c) is a graph of carrier density (cm⁻³) vs. position (Å) that shows the electron distribution within the material, wherein the In_{0.19}Al_{0.81}N carrier density is set to 4E19 cm⁻³ and the GaN carrier density is set at 5E18 cm⁻³, and wherein calculations are performed using BandEng.

In this example, the material of FIG. 2(a) is strongly n-type. In the band diagram of FIG. 2(b), it can be seen that the conduction band (upper solid line) dips below the Fermi level (dashed line) at every other interface. The band bending which is responsible for these dips is caused by the polarization charges discussed above.

It can further be seen in the charge distribution plot of FIG. 2(c) that, at each of the points where the conduction band dips below the Fermi level, there is a large spike in electron concentration. If such a structure is properly designed, virtually all of the free carriers within a material can be confined at these interfaces.

With the charge confined into relatively narrow channels at certain interfaces, it is now possible to deliberately exclude electron scattering centers from these regions. Typically, the dominant scattering mechanisms in these types of systems are ionized impurity scattering and alloy scattering. By keeping the dopant atoms confined to the high bandgap material and a number of nanometers away from the interface, ionized impurity scattering can be drastically reduced due to spatial separation.

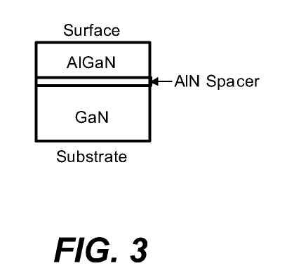

In addition, it has been shown that alloy scattering of electrons can be drastically reduced in AlGaN/GaN systems with the use of an AlN spacer. By including a very thin (˜0.5 nm) spacer, the charge carriers can be effectively spatially separated from the alloy scattering centers. Such a structure is shown in FIG. 3, which illustrates an AlGaN HEMT structure, wherein an AlN spacer is included to keep electrons away from alloy scattering centers in the AlGaN. In AlGaN/GaN HEMTs, a combination of these strategies has produced room temperature mobilities as high as 2000 cm²/VS, which is about four times higher than bulk GaN. [3]

These structures are generally thin films and can be grown by methods such as metal organic chemical vapor depositions (MOCVD), hydride vapor phase epitaxy (HVPE), or molecular beam epitaxy (MBE). It is also possible that this same effect could be obtained in bulk materials through mechanisms such as grain boundaries between dissimilar materials. Although the example given above describes a layered superlattice structure, it is possible to achieve similar polarization effects using arrays of wire or nanowire structures. This approach is also compatible with the deliberate introduction of nanoparticles for reduction of thermal conductivity or for thermionic energy filtering benefits. This approach is also capable of exploiting the advantages that low dimensional structures have shown in enhancing thermoelectric properties. It was first suggested by Hicks and Dresselhaus that quantum well structures could modify the density of states in a material and thereby improve the Seebeck coefficient. [5] The confinement in such systems is typically provided by combining materials with differing band gaps to confine charge carriers to the lower bandgap material. High levels of confinement can alternatively be achieved using the polarizations described above.

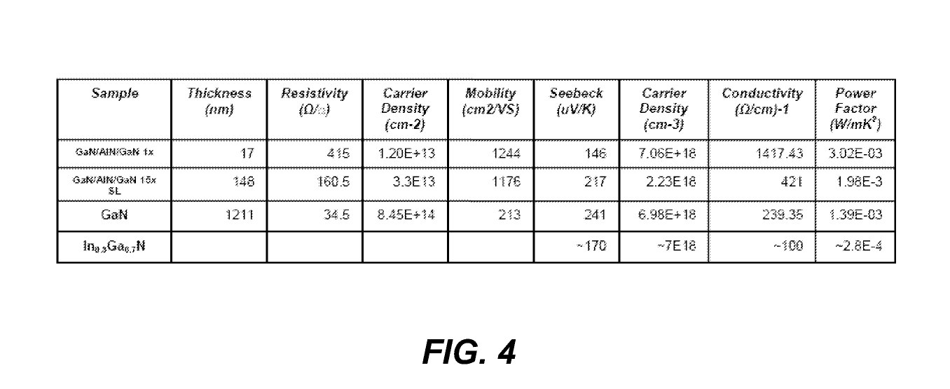

FIG. 4 is a Table that shows preliminary results and estimates for polarization-based, single layer GaN/AlN/AlGaN thermoelectrics and Gan/AlN/AlGaN superlattice thermoelectrics, grown by MOCVD, along with GaN and In_{0.3}Ga_{0.7}N for comparison, wherein data for In_{0.3}Ga_{0.7}N is taken from [7]. The sample labeled “AlGaN HEMT” is a single period of the structure shown in FIG. 3. This sample exhibits high mobility and low sheet resistance as well as a reasonable Seebeck coefficient. The sample labeled “17 nm period” approximates a superlattice of AlGaN HEMT structures with a 17 nm period. Such structures with have been shown experimentally for use as current spreading layers and maintain high electron mobility, although thermoelectric properties are not explored. [6] Using this 17 nm repeat period and the single layer electrical properties, the electrical conductivity and Seebeck coefficient for a GaN/AlN/AlGaN superlattice is estimated. This results in a power factor which is roughly a factor of two higher than silicon doped GaN and ten times higher than published values for InGaN. [7] The thermal properties of such a superlattice are difficult to estimate, but would be expected to be significantly lower than bulk GaN due scattering from the additional alloy elements, superlattice boundaries with the material, and the significant strain between the GaN and AlGaN layers.

Future work will include the growth of superlattice structures from various alloys and alloy compositions as well as the characterization of their thermoelectric properties.

### Process Steps

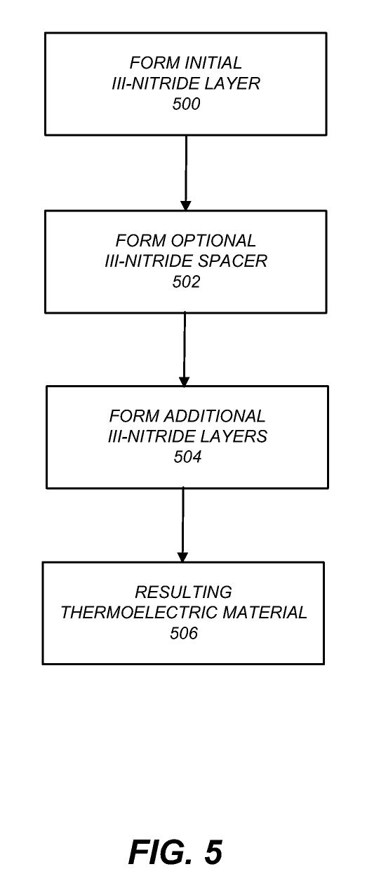

FIG. 5 is a flowchart illustrating one method of accomplishing the present invention, where the constituent materials are (Al, Ga, In) N or alloys of these materials.

Block 500 represents forming an initial III-nitride layer, such as GaN, with a growth (top) surface oriented along the c-axis. The initial III-nitride may be an epitaxial GaN layer grown on a substrate, such as a sapphire substrate, or a freestanding GaN layer, or a bulk GaN substrate, etc. The c-axis orientation means that the GaN has layered gallium and nitrogen atoms, where a first surface, e.g., the top surface, is Ga terminated, i.e., Ga-face, resulting in a Ga-polar surface, and a second surface, e.g., the bottom surface, is N terminated, i.e., N-face, resulting in an N-polar surface.

Block 502 represents the optional step of forming one or more III-nitride spacer layers or interlayers on the initial III-nitride layer For example, as noted above, it has been shown that alloy scattering of electrons can be drastically reduced in AlGaN/GaN systems with the use of an AN spacer. By including a very thin (˜0.5 nm) spacer, the high charge carrier concentration areas can be effectively spatially separated from the alloy elements or scattering centers.

Block 504 represents the step of forming one or more III-nitride layers on the spacer layers or the initial layer.

In this step, when a different material, for example, AlGaN or InAlN, is grown on top of GaN to form a heterointerface, the electronegativity difference between the atoms on each side of the interface causes what is termed as spontaneous polarization.

In addition to spontaneous polarization, piezoelectric polarization can be present at heterointerfaces within a material. This polarization is created when the materials on each side of the interface are piezoelectric materials. Since the materials used on each side of the interface often have different lattice constants, both sides of the interface are strained, and therefore piezoelectric electric fields are created.

Piezoelectric coefficients in III-Nitrides are also typically an order of magnitude larger than most III-V materials. [4] The combination of spontaneous and piezoelectric polarizations at these interfaces can create large polarization charges at interfaces for certain alloy compositions.

Note that the layers formed in Block 504 may comprise doped layers.

With the charge confined into relatively narrow channels at certain interfaces, it is possible to deliberately exclude electron scattering centers from these regions. Typically, the dominant scattering mechanisms in these types of systems are ionized impurity scattering and alloy scattering. By keeping the dopant atoms confined to the high bandgap material and a number of nanometers away from the interface, ionized impurity scattering can be drastically reduced due to spatial separation.

Generally, the structures formed in steps 502 and 504 are thin films and can be grown by epitaxial methods such as metal organic chemical vapor depositions (MOCVD), hydride vapor phase epitaxy (HVPE), or molecular beam epitaxy (MBE). However, it is also possible that these structures could be formed using bulk methods through mechanisms such as grain boundaries between dissimilar materials, where the bulk material is modified to include similar interfaces.

Note also that these steps 502 and 504 may be repeated to create, in one embodiment, a layered superlattice structure. However, other structures may be formed in other embodiments. For example, it is possible to achieve similar polarization effects by forming arrays of wire or nanowire structures. The approach of this invention is also compatible with the deliberate introduction of nanoparticles for reduction of thermal conductivity or for thermionic energy filtering benefits. In addition, the approach of this invention is also capable of exploiting the advantages that low dimensional structures have shown in enhancing thermoelectric properties, such as quantum well structures that modify the density of states in the material and thereby improve the Seebeck coefficient, where the confinement in such structures is typically provided by combining materials with differing band gaps to confine charge carriers to the lower bandgap material. High levels of confinement can alternatively be achieved using the polarizations described above.

Block 506 represents the end result of the process, namely a composition comprising a thermoelectric material with improved ZT that uses electric fields to spatially separate charge carriers and phonons. The electric fields are built in electric fields created by polarization charges present at interfaces with the material. The interfaces may be arranged in a layered superlattice structure, or the interfaces may be achieved using wire or nanowire structures.

In this material, charge carrier scattering centers are deliberately excluded from areas in the material with high charge carrier concentration, and phonon scattering centers are deliberately included in areas in the material with low charge carrier concentration.

Phonon scattering in low electron concentration regions of the material is achieved through alloy scattering induced in the material by binary, ternary, or quaternary alloys in the material.

The material may include nanoparticles, where the nanoparticles scatter phonons and further reduce thermal conductivity.

The confinement of charge carriers creates sharp features in the material's density of states, which can be used for the purpose of increasing the Seebeck coefficient and enhancing the power factor. This effect is in addition to the electron mobility enhancement achieved by spatially separating electrons from scattering centers.

The material may be grown by epitaxial methods, where epitaxial methods are used to create a layered superlattice in the material.

The material may be grown by bulk methods, where the material grown by the bulk methods is modified to include interfaces, and the electric fields are built in electric fields created by polarization charges present at the interfaces with the material.

The resulting thermoelectric materials, regardless of how prepared, can be processed into thermoelectric modules. Such modules can be fabricated through either traditional slicing and placement of individual thermoelements or through thin film processing techniques. These modules will result in higher efficiencies for both solid state cooling and power generation.

### Nomenclature

The terms “Group-III nitride” or “III-nitride” or “nitride” as used herein refer to any composition or material related to (Al, In, Ga) N semiconductors having the formula AlₓIn_{y}Ga_{z}N where 0≦x≦1, 0≦y≦1, 0≦z≦1, and x+y+z=1. These terms as used herein are intended to be broadly construed to include respective nitrides of the single species, Al, Ga, and In, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (Al, Ga, In) N component species are present, all possible compositions, including stoichiometric proportions as well as off-stoichiometric proportions (with respect to the relative mole fractions present of each of the (Al, Ga, In) N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of Group-III nitrides. When identifying crystal orientations, directions, terminations and polarities using Miller indices, the use of braces, {}, denotes a set of symmetry-equivalent planes, which are represented by the use of parentheses, ( ) The use of brackets, [], denotes a direction, while the use of brackets, <>, denotes a set of symmetry-equivalent directions.

Many Group-III nitride devices are grown along a polar orientation, namely a c-plane {0001} of the crystal, which exhibits a quantum-confined Stark effect (QCSE) due to the existence of strong piezoelectric and spontaneous polarizations. Other orientations in Group-III nitride devices exhibit decreasing polarization effects, such as devices grown along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero l Miller index. Subsequent semipolar layers are equivalent to one another, so the crystal will have reduced polarization along the growth direction.

### REFERENCES

The following publications are incorporated by reference herein:

[1] H Bottner, G Chen, and R Venkatasubramanian, Mrs Bulletin 31, 211-217 (2006).

[2] W Kim, J Zide, A Gossard, D Klenov, S Stemmer, A Shakouri, and A Majumdar, Physical Review Letters 96, (2006).

[3] R. Gaska, J. W. Yang, a. Osinsky, Q. Chen, M. Asif Khan, a. O. Orlov, G. L. Snider, and M. S. Shur, Applied Physics Letters 72, 707 (1998).

[4] Hadis Morkoc, Handbook of Nitride Semiconductors and Devices (Wiley-VHC, 2008).

[5] L D Hicks and M S Dresselhaus, Physical Review B 47, 12727-12731 (1993).

[6] Sten Heikman, Stacia Keller, Daniel S. Green, Steven P. DenBaars, and Umesh K. Mishra, Journal of Applied Physics 94, 5321 (2003).

[7] B N Pantha, R Dahal, J Li, J Y Lin, H X Jiang, and G Pomrenke, Journal of Electronic Materials 38, 1132-1135 (2009).

[8] D. Brown, PhD Thesis, “Growth of N-polar GaN-based Materials and High Electron Mobility Transistors by Metal Organic Chemical Vapor Deposition” (2010).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A composition, comprising:
a thermoelectric material that uses electric fields to spatially separate charge carriers and phonons.

2. The composition of claim 1, where the electric fields are built in electric fields created by polarization charges present at interfaces with the material.

3. The composition of claim 2, where the interfaces are arranged in a layered superlattice.

4. The composition of claim 2, where the interfaces are achieved using wire or nanowire structures.

5. The composition of claim 1, where charge carrier scattering centers are deliberately excluded from areas in the material with high charge carrier concentration.

6. The composition of claim 1, where phonon scattering centers are deliberately included in areas in the material with low charge carrier concentration.

7. The composition of claim 6, where phonon scattering in low electron concentration regions of the material is achieved through alloy scattering induced in the material by inclusion of binary, ternary, or quaternary alloys in the material.

8. The composition of claim 1, where nanoparticles are included in the material.

9. The composition of claim 8, where the nanoparticles scatter phonons and further reduce thermal conductivity.

10. The composition of claim 1, where the confinement of charge carriers creates sharp features in the material's density of states for the purpose of increasing a Seebeck coefficient and enhancing a power factor.

11. The composition of claim 1, where the material comprises (In, Al, Ga) N.

12. The composition of claim 11, where AlN interlayers are included in the material to spatially separate alloy elements from high charge carrier concentration areas.

13. The composition of claim 1, where the material is grown by epitaxial methods.

14. The composition of claim 13, where epitaxial methods are used to create a layered superlattice in the material.

15. The composition of claim 1, where the material is grown by bulk methods.

16. The composition of claim 15, where material grown by the bulk methods is modified to include interfaces, and the electric fields are built in electric fields created by polarization charges present at the interfaces with the material.

17. A method of fabricating a thermoelectric material, comprising:
(a) forming an initial III-nitride layer with a growth surface oriented along a c-axis;
(b) optionally forming one or more III-nitride spacer layers on the initial III-nitride layer; and
(c) forming one or more III-nitride layers on the spacer layers or the initial layer to create a thermoelectric material with improved ZT that uses electric fields to spatially separate charge carriers and phonons.

18. The method of claim 17, wherein the electric fields are built in electric fields created by polarization charges present at interfaces with the material.

19. The method of claim 17, wherein the III-nitride layers formed on the spacer layers or the initial layer comprise doped layers.

20. The method of claim 17, wherein the forming steps (a)-(c) are repeated to create a layered superlattice structure.
